(19) United States
(12) Patent Application Publication
(10) Pub. No.: US 2001/0002161 A1
(43) Pub. Date: May 31, 2001

(54) Fixing mechanism for printed circuit board and containing case for printed circuit board

(76) Inventor: Takayasu Takayanagi, Tokyo (JP)

Correspondence Address: Pillsbury Madison & Sutro LLP, Intellectual Property Group, 1100 New York Avenue, N.W., Ninth Floor, East Tower, Washington, DC, 20005-3918, US

(21) Appl. No.: 09/725,573

(22) Filed: Nov. 30, 2000

(30) Foreign Application Priority Data
Nov. 30, 1999 (JP) 11-341261

(51) Int. Cl. H05K 7/14

(52) U.S. Cl. 361/741

(57) ABSTRACT

A mechanism for fixing a printed circuit board to a case has a guide support portion and a stopper. The guide support portion guides the printed circuit board in a direction of insertion and pulling out of the printed circuit board and supports the printed circuit board. The guide support portion is disposed in the case. The stopper engages with the printed circuit board which is inserted into the guide support portion, and fixes the printed circuit board to the case.

### BACKGROUND OF THE INVENTION

1. Field of the Invention

The present invention relates to a mechanism for fixing printed circuit boards and a case for containing printed circuit boards, the mechanism or the case is attached to an apparatus body or the like which is provided with the printed circuit boards. Particularly, the present invention relates to a printed circuit board fixing mechanism that can detachably fix a plurality of printed circuit boards, respectively, and to a printed circuit board containing case that is provided with the mechanism.

2. Description of Related Art

In earlier technology, as a structure for fixing a plurality of printed circuit boards (hereinafter, it may be simply referred to “PCB”s) in an unit of product, a structure as shown in FIG. 5 has generally been known. The unit is used with being fixed to and connected with a product body. As shown in FIG. 5, with the fixing structure for a plurality of PCBs in the unit, PCBs 7 and 7A are layered above a bottom board of an unit body 6 therein. The PCBs 7 and 7A are fixed to the bottom board through pillars 8 and pillars 9 at four corners of the PCBs 7 and 7A between the PCBs 7 and 7A or between the PCB 7A and the bottom board.

As shown in FIG. 5, the pillars 8 have lengths which are different from lengths of the pillars 9. The lengths of the pillars 8 and 9 are corresponding to spaces between the PCBs to be fixed and the number thereof.

However, when maintenance of the PCBs 7 and 7A are carried out, or when electronic parts which are packaged on the PCBs 7 and 7A are adjusted, because respective PCBs 7 and 7A are fixed to each other by a plurality of the pillars 8 and 9, all the pillars 8 and 9 are required to be removed from the PCBs 7 and 7A so that such a work can be performed.

The pillars 8 and the pillars 9 having different lengths from each other are removed from the PCBs 7 and 7A for the work. Thereafter, when the PCBs are attached to the unit again by the pillars 8 and 9, pillars corresponding to the PCBs to be fixed are selected among a plurality of the removed pillars having different lengths each other. Then, the pillars are attached to the PCBs. Thus, the work becomes complicated. Furthermore, as the number of PCBs increases, the number of pillars increases, thereby the pillars are apt to be easily lost.

### SUMMARY OF THE INVENTION

The present invention was developed in view of the above-described problems. Therefore, an object of the present invention is to provide a mechanism for fixing printed circuit boards (PCBs) and a case for containing PCBs, that easily enable attachment and detachment of a plurality of PCBs, respectively, even if the mechanism and the case are applied to an unit of product which is provided with the PCBs.

In order to accomplish the above-described object, in one aspect of the present invention, a mechanism for fixing a PCB to a case comprises: a guide support portion for guiding the PCB in a direction of insertion and pulling out of the PCB, and for supporting the PCB, the guide support portion being disposed in the case; and a stopper for engaging with the PCB which is inserted into the guide support portion, and for fixing the PCB to the case.

According to the mechanism for fixing a PCB, the PCB is supported by the guide support portion. By engaging the stopper with the PCB, the PCB is fixed to the guide support portion. Thus, it is possible to easily fix the PCB to the case in which the guide support portion is disposed, merely by engaging the stopper with the PCB.

In addition, differing from the earlier technology, the plural pillars are not required to fix the PCB. Thus, during the fixing operation of the PCBs, the parts are not lost, and the fixing operation is performed in a short time.

The case in which the guide support portion is disposed may be a case into which the guide support portion is integrated, or may be walls which are disposed to face to each other. When the facing walls constitute the case, the guide support portion is disposed between the walls. The PCB is inserted into the guide support portion, thereby the PCB is disposed between the walls. Thus, the PCB is contained between the walls as the case.

The guide support portion may have grooved portions which are disposed to face to each other. Edge portions of the PCB may be inserted into the respective grooved portions. Thus, the PCB may be supported by the grooved portions at the edge portions of the PCB. The guide support portion may have a structure that holds the PCB therebetween, as an alternative to the grooved portions. The structure holds the PCB in directions that are perpendicular to a direction of insertion and pulling out of the PCB. The structure may guide the PCB in the direction of insertion and pulling out of the PCB, and support the PCB movably in the direction of insertion and pulling out. For example, two projecting rows may be formed on guide members which are disposed to face to each other. The two projecting rows extend in the direction of insertion of the PCB so as to project inside, and hold the inserted PCB between the two projecting rows.

With the mechanism for fixing a PCB, the guide support portion may support a plurality of PCBs. The stopper may be attachable to and detachable from the guide support portion. The stopper may engage with a plurality of the PCBs.

According to the mechanism for fixing a PCB, the effect above-described may be obtained. Furthermore, the stopper may be detachably attached to the guide support portion and the stopper may engage with a plurality of the PCBs, thereby the stopper fix a plurality of the PCBs.

Thus, a plurality of the PCBs may easily be fixed to the case where the guide support portion is disposed.

In order to detach a plurality of the PCBs from the case, by detaching the stopper from the guide support portion, the engagement between the stopper and the PCBs is released. Thus, a plurality of the PCBs may be detached from the case.

That is, the PCBs may be pulled out from the guide support portion to be detached therefrom, merely by detaching the stopper from the guide support portion. Thus, differing from the earlier technology where all pillars are detached from the PCBs, the time for detaching of the PCBs from the case may be reduced.

Thus, the attachment and detachment of the plural PCBs, particularly, the attachment and detachment of an arbitrary PCB among the plural PCBs may be easily performed. Therefore, when the maintenance of the PCBs which are fixed in the case is carried out or when parts of the PCBs are exchanged, operating efficiency may be improved.

With the mechanism for fixing a PCB, the stopper may engage with a cut-out portion which is formed in the PCB.

According to the mechanism, the effects as above-described may be obtained. In addition, the PCB may be fixed to the case by that the stopper engages with a cut-out portion. Thus, by a simple structure, the PCB may be certainly fixed to the case with the guide support portion.

With the mechanism for fixing a PCB, the stopper may have a grooved portion which fits an edge of the PCB, when the stopper engages with the cut-out portion of the PCB.

According to the mechanism, the stopper may have a grooved portion which fits the edge of the PCB when the stopper engages with the PCB, thereby it may be more certain to fix the PCB to the case.

In accordance with another aspect of the present invention, a case for containing a printed circuit board (PCB) comprises the above-described mechanism for fixing a PCB.

According to the case for containing a PCB, the effects as above-described may be obtained.

With the case for containing a PCB, the guide support portion may be detachably attached to an inside of a body of the case.

According to the case for containing a PCB, the effects as above-described may be obtained. In addition, the guide support portion may be changed together with the stopper, corresponding to the PCB. Thus, various types of PCBs or various sizes of PCBs may be fixed in the body of the case.

### BRIEF DESCRIPTION OF THE DRAWINGS

The above and other objects, features and advantages of the invention will become more apparent from the following description taken in conjunction with the accompanying drawings wherein like references refer to like parts and wherein:

FIG. 1 is a perspective view of a case for containing a PCB according to one embodiment of the present invention, showing that stoppers are detached from a case body;

FIG. 2 is a perspective view of the case for containing a PCB, showing that stoppers are attached to the case body;

FIG. 3 is an enlarged view of engaging portions between the stoppers and the PCB;

FIG. 4 is a perspective view of a case for containing a PCB according to a modified embodiment of the present invention; and

FIG. 5 is a perspective view of a main portion of an unit product, showing a structure for fixing a plurality of PCBs in earlier technology.

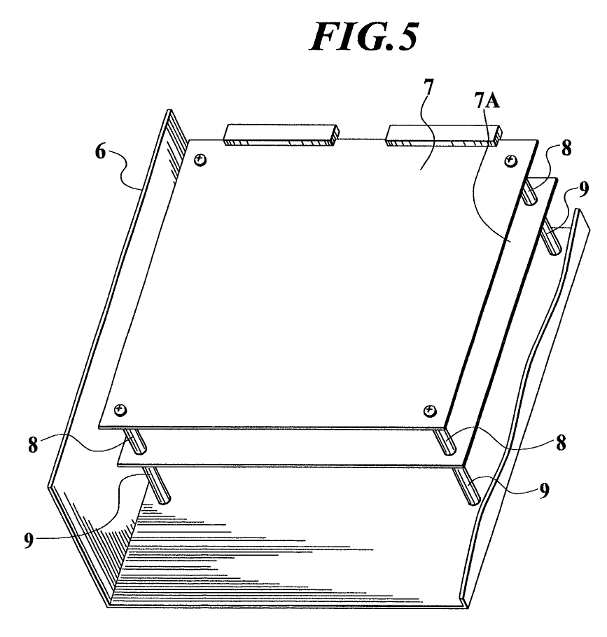

### PREFERRED EMBODIMENT OF THE INVENTION

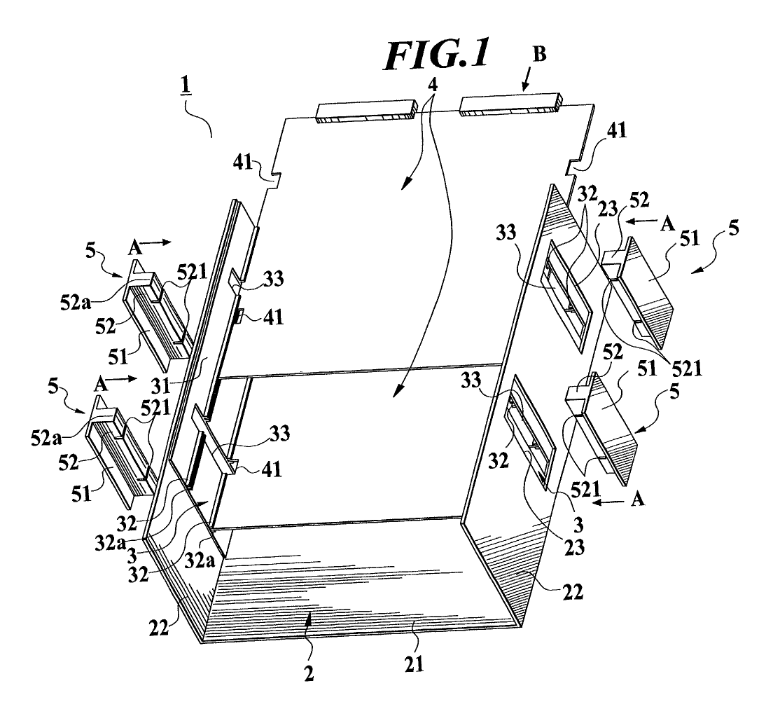

Hereinafter, embodiments of a printed circuit board (PCB) containing case according to the present invention will be explained, referring to FIGS. 1 to 4.

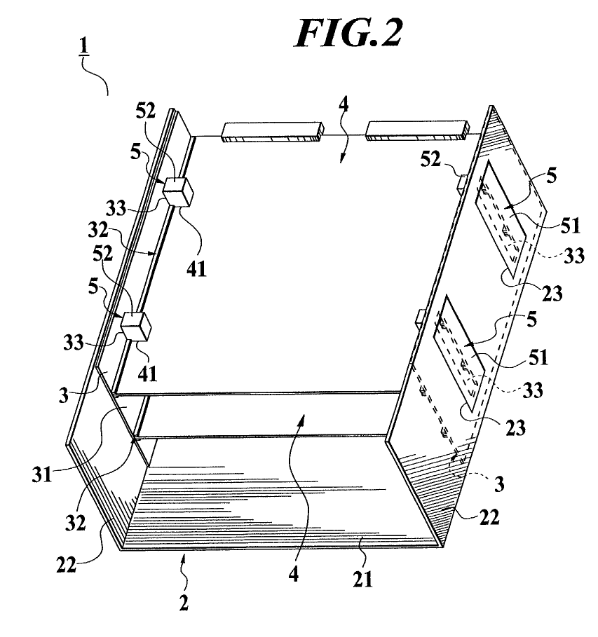

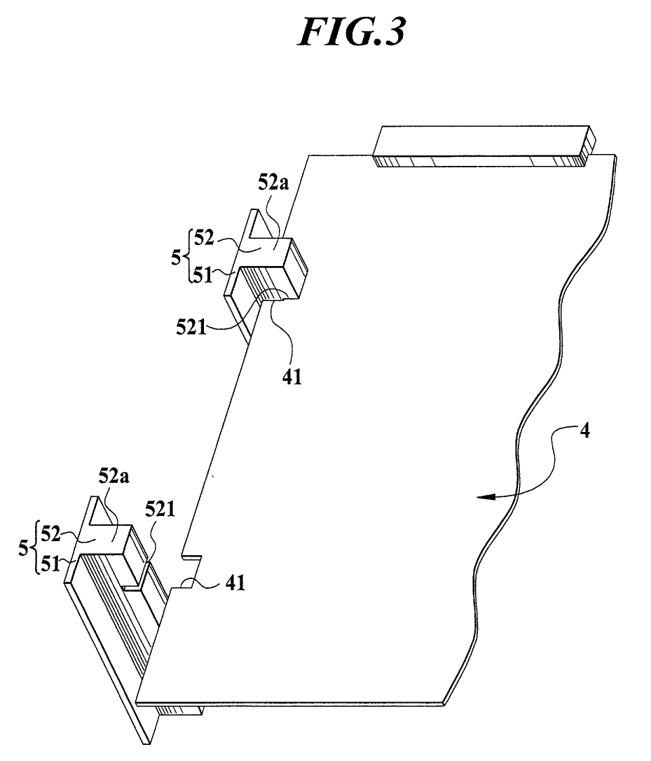

FIG. 1 is a perspective view of a PCB containing case as one embodiment of the present invention, showing that stoppers are detached from a body of the PCB containing case. FIG. 2 is a perspective view of the PCB containing case where the stoppers are attached to the case body. FIG. 3 is an enlarged view of engaging portions between the stoppers and the PCBs.

As shown in these drawings, the PCB containing case 1 has a case body portion 2, guide members (guide supporting portions) 3, PCBs 4, stoppers 5. The guide members 3 are detachably attached to the case body portion 2. The stoppers 5 are detachable from and attachable to the case body portion 2 and the guide members 3.

The case body portion 2 has a bottom board portion 21, and case side walls 22 which are disposed upward in a vertical direction at both right and left edge portions of the bottom board portion 21. The case side walls 22 face to each other. The case body portion 2 has a structure so that the PCBs 4 will be set inside the bottom board portion 21 and the case side walls 22, i.e., in the case body portion 2, with the PCBs 4 layered.

The right and left case side walls 22 which face to each other are provided with side wall opening portions 23 through the case side walls 22 with determined spaces so that inside and outside of the case side walls 22 are led to each other. The stoppers 5 (these will be described later) are inserted from the outside into the side wall opening portions 23. With this embodiment, the side wall opening portion 23 has a shape of a rectangle which is long longitudinally, i.e., which is long in the vertical direction.

The guide members 3 are attached to the inside of the right and left case side walls 22 and face to each other. The plural PCBs 4 are inserted into the guide members 3. The guide members 3 are for positioning the PCBs 4 at predetermined positions.

The guide member 3 has a fixed portion 31, guide portions 32 and opening portions 33. The fixed portion 31 is fixed on an inner surface of the case side wall 22. The guide portions 32 are disposed on the fixed portion 31 and provided with grooved portions 32a which guide the PCBs 4 back and forth (in a direction of insertion and pulling out of the PCBs 4) with side edge portions of the PCBs 4 fitted in the grooved portions 32a. The stoppers 5 are inserted into the opening portions 33.

The grooved portions 32a extend back and forth of the case body portion 2. The grooved portions 32a of one guide member 3 are disposed at positions corresponding to grooved portions 32a of the other guide member 3 which faces to one guide member 3. A width or space (length in a vertical direction) of the grooved portion 32a is corresponding to a thickness of the PCB 4. The side edge portions of the PCBs 4 are fitted in the grooved portions 32a which face to each other, and slid from back side. Thus, the PCBs 4 are inserted about horizontally in the case body portion 2, so that the PCBs 4 are positioned by the guide members 3 both up and down (vertically) and right and left.

The opening portions 33 are formed in the fixed portions 31, and correspond to the side wall opening portions 23 when the guide members 3 are attached to the case side walls 22. The opening portions 33 are formed so that opening areas of the opening portions 33 will be smaller than that of the side wall opening portions 23.

Thus, when the case side wall 22 of the case body portion 2 is viewed from the outside, a part of a rear surface of the fixed portion 31 of the guide member 3 is exposed to the outside at both sides of the opening portion 33 within the side wall opening portion 23. When the stopper 5 is inserted into the opening portion 33 from the outside (outside of the side wall 22), a flanged portion 51 of the stopper 5 engages with the exposing part of the rear surface of the fixed portion 31 within the side wall opening portion 23.

The PCB 4 is cut out at both right and left edge portions thereof in a direction which is perpendicular to the direction that the PCB 4 is inserted between the guide members 3 (back and forth), so that cut-out portions 41 are formed. The cut-out portions 41 are formed so that they will correspond to the opening portions 33 when the PCB 4 is guided to a predetermined fixing position by the guide members 3. With this embodiment, each cut-out portion 41 of the upper and lower PCBs 4 is visible from the outside through the side wall opening portions 23 and the opening portions 33.

These cut-out portions 41 engage with projecting portions 52 of the stoppers 5 when the stoppers 5 are inserted from the outside through the guide members 3. Thus, the PCBs 4 do not move back and forth, i.e., in the direction that the grooved portions 32a extend. Therefore, the PCBs 4 are fixed in the case 1 at the predetermined positions.

The stoppers 5 are inserted into the inside of the case body portion 2 through the side wall opening portions 23 at right and left of the case body portion 2. The stopper 5 has the flanged portion 51 and the projecting portion 52. When the stopper 5 is inserted into the inside of the case body portion 2, the flanged portion 51 fills the side wall opening portion 23 and engages with the fixed portion 31 of the guide member 3 within the side wall opening portion 23. When the stopper 5 is inserted into the inside of the case body portion 2, the projecting portion 52 projects into the inside of the case body portion 2 from the side wall opening portion 23 and engages with the cut-out portions 41 of the PCBs 4.

With this embodiment, the flanged portion 51 has a board-like shape which corresponds to the side wall opening portion 23. A handle may be disposed on an outside surface of the flanged portion 51 so that an operator can grasp the stopper 5 and easily pull it out.

The projecting portion 52 has a shape so that it will be inserted into the opening portion 33 and fit therein.

Thus, when the projecting portion 52 is inserted into the inside of the guide member 3, side surfaces of the projecting portion 52, the side surfaces adjoining the flanged portion 51, engage with peripheral portions of the opening portion 33. Therefore, the projecting portion 52 moves neither up and down nor back and forth.

As shown in FIG. 3, grooved portions 521 are formed in top edge portions 52a of the projecting portions 52. When the projecting portions 52 are fitted in the cut-out portions 41 of the PCBs 4, edge portions of the cut-out portions 41 fit in the grooved portions 521. The edge portions of the cut-out portions 41 are on lateral sides (in the direction of right and left) of the PCBs 4. FIG. 3 shows a front side stopper 5 which is before engaging with the PCB 4, and a back side stopper 5 which engages with the PCB 4.

According to the structure, the top edge portions 52a of the stoppers 5 and the lateral side edge portions of the cut-out portions 41 of the PCB 4 engage with each other. Thus, when the PCBs 4 have been guided to and supported at the predetermined positions, an effect of positioning and fixing the PCBs 4 by stoppers 5 becomes more certain. The plural grooved portions 521 are formed in the stopper 5. The number of grooved portions 521 corresponds to the number of PCBs 4 which are contained in the case body portion 2. With this embodiment, two grooved portions 521 are formed in the projecting portion 52 of the stopper 5 so that it can fix two PCBs 4.

As above-described, the guide members 3, the stoppers 5 and the cut-out portions 41 of the PCBs 4 or the like constitute a PCB fixing mechanism that fixes the PCBs 4 in the case body portion 2 of the case 1.

Operation of the case 1 as above-described will be explained.

At first, the plural PCBs 4 are inserted into the case body portion 2 where the guide members 3 are attached to the case side walls 2, from one side of front or back (it is from the back side in FIG. 1). At this time, both right and left edge portions of the PCBs 4 are fitted in the grooved portions 32a of the guide members 3 which face to each other. In FIG. 1, see the upper PCB 4 and an arrow B.

Then, the PCB 4 is moved to the predetermined position where the PCB 4 is positioned for fixing, so that the cut-out portions 41 and the opening portions 33 face to each other (see the lower PCB 4 in FIG. 1). Particularly, the side wall opening portions 23 and the opening portions 33 face to the lateral side edge portions of the cut-out portions 41.

The stoppers 5 are inserted into the side wall opening portions 23 of the case body portion 2 in a direction of arrows A (see FIG. 1) from the both sides. The projecting portions 52 of the stoppers 5 are inserted into and engaged with the cut-out portions 41. At this time, the grooved portions 521 of the top edge portions 52a of the projecting portions 52 engage with the lateral side edge portions of the cut-out portions 41.

Thus, the PCBs 4 are positioned and fixed in the case body portion 2.

As above-described, by engaging the stoppers 5 with the PCBs 4 which are supported by the guide members 3, the PCBs 4 can easily be fixed to the case body portion 2 which is provided with the guide members 3.

In addition, differing from the earlier technology, the plural pillars are not required for fixing of the PCBs 4. Thus, during the fixing operation of the PCBs 4, the parts are not lost, and the fixing operation is performed in a short time.

In order to detach the PCBs 4 from the case body portion 2, the stoppers 5 are detached from the guide members 3, i.e., the stoppers 5 are pulled out toward the outside of the case body portion 2. Thereby, the engagements between the projecting portions 52 of the stoppers 5 and the cut-out portions 41 are easily released.

Furthermore, after detaching the stoppers 5 from the case body portion 2, the plural PCBs 4 and 4 are held in the grooved portions 32a of the guide portions 32, thereby only arbitrary PCB 4 can be detached from the case body portion 2 by pulling it out therefrom.

Thus, the attachment and detachment of the plural PCBs 4 and 4, particularly, the attachment and detachment of the arbitrary PCB 4 between the plural PCBs 4 and 4 can be easily performed. Therefore, when the maintenance of the PCBs 4 which are fixed in the case 1 is carried out or parts of the PCBs 4 is exchanged, operating efficiency can be improved.

The above-described guide members 3 are detachably attached to the case body portion 2. The guide members 3 and stoppers 5 may be changed according to shapes of PCBs which are fixed in the case body portion 2 or to the number of the PCB.

That is, the number of grooved portions of the guide members and the positions where the grooved portions are formed may be changed. Corresponding to the guide members, the number of grooved portions of the stoppers and the positions where the grooved portions are formed may be changed. Thereby, the number of the PCBs, the shapes thereof, or sizes thereof which are contained in the case body portion 2 can be changed.

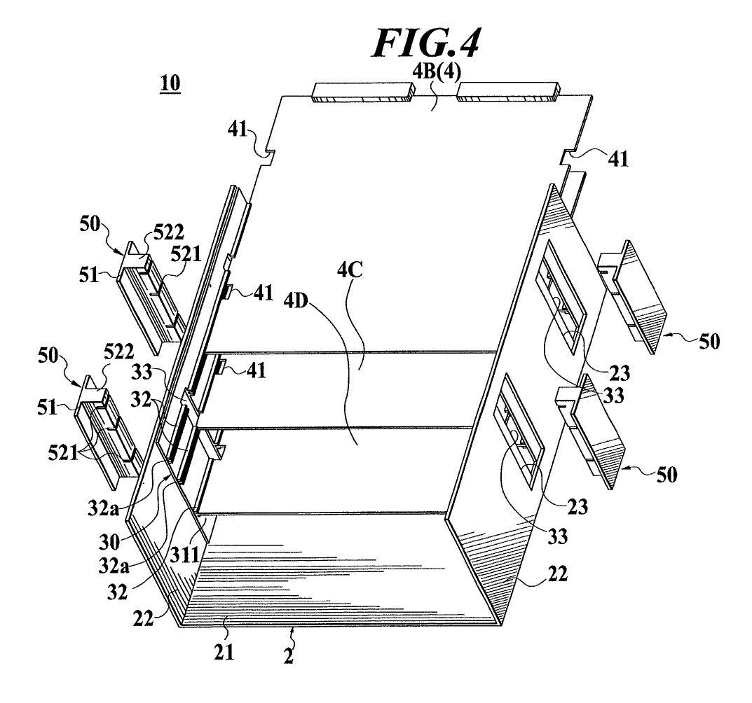

An example of such a case as a modified embodiment is shown in FIG. 4.

FIG. 4 is a perspective view showing the PCB containing case according to the modified embodiment of the present invention. With the case 10, more PCBs are fixed in the case body portion 2 than in the case 1. With the case 10 of FIG. 4, only structures of guide members and stoppers which are made to correspond to the number of the PCBs are different from those of the case 1, and other structures are the same as those of the case 1. Thus, only different structures will be explained. To structural members, elements or the like corresponding to those of case 1, the same reference numerals are attached, and the detailed explanation for them is properly omitted.

The case 10 has the case body portion 2 which is the same as that of the case 1. The side wall opening portions 23 are formed through the case side walls 22.

Second guide members 30 are detachably attached to the case body portion 2. The second guide members 30 have more grooved portions 32a than the guide members 3. The PCBs 4B, 4C and 4D are guided and supported by the second guide members 30.

The second guide member 30 has a fixed portion 311, the guide portions 32 and the opening portions 33. The guide portions 32 are disposed on the fixed portion 311 and provided with grooved portions 32a. The grooved portions 32a extend back and forth. The PCBs 4B to 4D are inserted into the grooved portions 32a from the back side. The grooved portions 32a guide the PCBs 4B to 4D to predetermined positions with side edge portions of the PCBs 4B to 4D fitted in the grooved portions 32a. Stoppers 50 which will be described later are inserted into the opening portions 33.

The plural guide portions 32 are horizontal and parallel to each other, and extend back and forth.

Three guide portions 32 are disposed on the guide member 30. A length between the middle guide portion and the bottom guide portion is longer than that between the top guide portion and the middle guide portion.

With the modified embodiment, the widths of the grooved portions 32a of the guide portions 32 are corresponding to the thickness of the PCBs 4B to 4D.

By preparing the guide members 30 which are corresponding to the PCBs 4B to 4D, the PCBs 4B to 4D which are different types and have different shapes can be fixed in the case 10.

The stopper 50 differs from the stopper 5 in that the three grooved portions 521 are formed in a projecting portion 522. Other structures of the stopper 50 are the same as that of the stopper 5.

The grooved portions 521 correspond to the grooved portions 32a of the guide portions 32. When the stopper 50 is inserted into the inside of the case 10 through the opening portion 33 of the guide member 30, the grooved portions 521 are disposed along the grooved portions 32a which extend back and forth.

Thus, even if many PCBs are required to be fixed, the same effect as that of the case 1 can be obtained.

In the cases 1 and 10 according to the above-described embodiments, two or three PCBs are fixed. However, the present invention is not limited to the embodiments, one PCB or more than three PCBs may be fixed by similar structures.

Although the cases 1 and 10 are disclosed as the embodiments of the present invention, the present invention may be applied to other types of devices to which PCBs are easily attached detachably.

From the foregoing description, one skilled in the art can easily ascertain the essential characteristics of this invention, and without departing from the spirit and scope thereof, can make various changes and modifications of the invention to adapt it to various usage and conditions.

The entire disclosure of Japanese Patent Application No. 11-341261 filed on Nov. 30, 1999 including specification, claims, drawings and summary are incorporated herein by reference in its entirety.

What is claimed is:

1. A mechanism for fixing a printed circuit board to a case, the mechanism comprising:
a guide support portion for guiding the printed circuit board in a direction of insertion and pulling out of the printed circuit board, and for supporting the printed circuit board, the guide support portion being disposed in the case; and
a stopper for engaging with the printed circuit board which is inserted into the guide support portion, and for fixing the printed circuit board to the case.

2. The mechanism for fixing a printed circuit board to a case as claimed in claim 1, wherein the guide support portion supports a plurality of printed circuit boards, the stopper is attachable to and detachable from the guide support portion, and the stopper engages with a plurality of the printed circuit boards.

3. The mechanism for fixing a printed circuit board to a case as claimed in claim 1, wherein the stopper engages with a cut-out portion which is formed in the printed circuit board.

4. The mechanism for fixing a printed circuit board to a case as claimed in claim 3, wherein the stopper has a grooved portion which fits an edge of the printed circuit board when the stopper engages with the cut-out portion of the printed circuit board.

5. A case for containing a printed circuit board, comprising:
a guide support portion for guiding the printed circuit board in a direction of insertion and pulling out of the printed circuit board, and for supporting the printed circuit board, and the guide support portion being disposed in the case; and
a stopper for engaging with the printed circuit board which is inserted into the guide support portion, and for fixing the printed circuit board to the case.

6. The case for containing a printed circuit board as claimed in claim 5, wherein the guide support portion supports a plurality of printed circuit boards, the stopper is attachable to and detachable from the guide support portion, and the stopper engages with a plurality of the printed circuit boards.

7. The case for containing a printed circuit board as claimed in claim 5, wherein the stopper engages with a cut-out portion which is formed in the printed circuit board.

8. The case for containing a printed circuit board as claimed in claim 7, wherein the stopper has a grooved portion which fits an edge of the printed circuit board, when the stopper engages with the cut-out portion of the printed circuit board.

9. The case for containing a printed circuit board as claimed in claim 8, wherein the guide support portion is detachably attached to an inside of a body of the case.
